(19) United States
(12) Patent Application Publication
(10) Pub. No.: US 2017/0053042 A1
(43) Pub. Date: Feb. 23, 2017

(54) HOLOGRAPHIC BUILDING INFORMATION UPDATE

(71) Applicants: Benjamin John Sugden, Redmond, WA (US); James L. Nance, Kirkland, WA (US); John Charles Howard, Redmond, WA (US); Marcus Tanner, Redmond, WA (US); James T. Reichert, Jr., Redmond, WA (US); Jonathan R. Christen, Bothell, WA (US)

(72) Inventors: Benjamin John Sugden, Redmond, WA (US); James L. Nance, Kirkland, WA (US); John Charles Howard, Redmond, WA (US); Marcus Tanner, Redmond, WA (US); James T. Reichert, Jr., Redmond, WA (US); Jonathan R. Christen, Bothell, WA (US)

(21) Appl. No.: 14/830,212

(22) Filed: Aug. 19, 2015

(51) Int. Cl. G06F 17/50; G06T 19/00; G06F 3/01; G02B 27/01; H04N 5/232

(52) U.S. Cl. CPC G06F 17/5004; G02B 27/0172; G02B 27/0179; H04N 5/23229; G06F 3/012; G06T 19/006; G02B 2027/0138; G02B 2027/0141; G02B 2027/0174; G02B 2027/014

(57) ABSTRACT

A method is disclosed that includes accessing a building information modeling database comprising building information data of a structure. A position of a head-mounted display device with respect to the structure may be tracked, with the head-mounted display device comprising an at least partially see-through display. In response to a portal user input, a world-locked holographic portal may be displayed via the device on a surface of the structure, where the portal comprises a world-locked holographic representation of a portion of the structure otherwise hidden from view by the surface. In response to an operation user input, a virtual operation is performed on the structure, and the building information modeling database is updated based on the virtual operation.

### BACKGROUND

Architects, structural engineers, construction personnel and others associated with constructing, altering, and/or maintaining a structure utilize a wide variety of data related to such projects. Such data may include, for example, blueprints, architectural drawings, schematics, identifiers, sketches, textual notations, voice annotations, photos, videos, 2 dimensional geometry, 3 dimensional geometry, tasks, schedules, additions to a physical space, alterations to a physical space, instructions, project status information, bills of materials, material properties, measurements, electrical diagrams, plumbing diagrams, personnel information, etc.

Keeping such data current and otherwise managing the many types of such data can prove challenging. For example, different aspects and systems of a building, such as structural, electrical, and plumbing, may be recorded and maintained in different documents. Such data may be utilized and consumed on a jobsite in 2 dimensional paper documents, such as blueprints, drawings, and schematics. Each such document provides just a partial understanding of the complete structure. Additionally, keeping such data current, such as by making changes or annotations on-site and based on real world information, is often impractical if not impossible.

### SUMMARY

To address these issues, a head-mounted display device and method are provided for updating a building information modeling database. The head-mounted display device may comprise a camera configured to capture images and an at least partially see-through display. A memory may hold instructions executable by a processor, with the instructions executable to access a building information modeling database comprising building information data of a structure. A position of the head-mounted display device may be tracked with respect to the structure.

In response to a portal user input, a world-locked holographic portal may be displayed on a surface of the structure, wherein the portal comprises a world-locked holographic representation of a portion of the structure otherwise hidden from view by the surface. In response to an operation user input, a virtual operation may be performed on the structure. The building information modeling database may be updated based on the virtual operation.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a schematic view of a computing device and a head-mounted display device according to an example of the present description.

FIG. 2 is a schematic view of a head-mounted display device according to an example of the present disclosure.

FIG. 3 shows a user wearing head-mounted display device of FIG. 2 and facing a surface of a structure according to an example of the present description.

FIG. 4 shows the user from FIG. 3 viewing a holographic door on the surface of the structure according to an example of the present description.

FIG. 5 shows the user from FIG. 3 viewing a holographic portal on the surface of the structure according to an example of the present description.

FIG. 6 shows a holographic comment according to an example of the present description.

FIG. 7 shows the user from FIG. 3 virtually altering a physical feature of the structure according to an example of the present description.

FIG. 8 shows the user from FIG. 7 viewing a virtual door added to the structure according to an example of the present description.

FIG. 9 shows the user from FIG. 3 viewing a holographic installation template according to an example of the present description.

FIG. 10 shows the user from FIG. 9 viewing an actual window installed using the holographic installation template of FIG. 9 according to an example of the present description.

FIG. 11 shows the user from FIG. 3 viewing holographic eligible and ineligible locations according to an example of the present description.

FIG. 12 shows the user from FIG. 3 viewing a holographic component at a proposed location according to an example of the present description

FIGS. 13A and 13B are a flow chart of a method of updating a building information modeling database according to an example of the present description.

FIG. 14 shows a computing system according to an embodiment of the present description.

### DETAILED DESCRIPTION

The present descriptions relate to utilizing a head-mounted display (HMD) device to update a building information modeling (BIM) database. The HMD device may comprise an augmented reality display device that includes an at least partially see-through display configured to visually augment a view of a real world three dimensional environment through the display. Building information data stored in a BIM database may comprise digital representations of physical and functional features and characteristics of a structure, such as a building or facility. As noted above, examples of building information data may include blueprints, architectural drawings, schematics, identifiers, sketches, textual notations, voice annotations, photos, videos, 2 dimensional geometry, 3 dimensional geometry, tasks, schedules, additions to a physical space, alterations to a physical space, instructions, project status information, bills of materials, material properties, measurements, electrical diagrams, plumbing diagrams, personnel information, etc.

As described in more detail below, in some examples display data may be transmitted to an HMD device to cause the device to display one or more holograms with respect to a structure. In some examples, a world-locked holographic portal may be displayed on a surface of the structure, with the portal comprising a world-locked holographic representation of a portion of the structure otherwise hidden from view. In other examples, a world-locked holographic component may be displayed at a proposed location in the structure. In other examples, a world-locked holographic installation template may be displayed at a location in the structure. In other examples, a holographic comment may be displayed to a wearer of the HMD device.

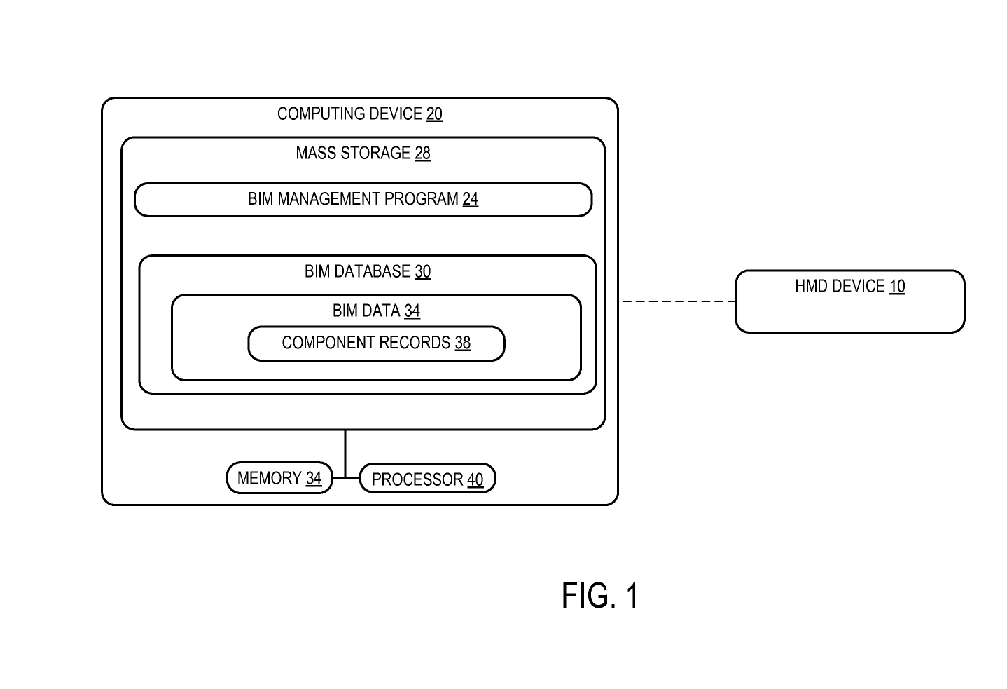

FIG. 1 is a schematic illustration of an HMD device 10 that is communicatively coupled to a computing device 20 according to an example of the present disclosure. As described in more detail below, the HMD device 10 may include an at least partially see-through stereoscopic display that may be configured to visually augment a view of a real world three dimensional environment by the user through the display. For example, the HMD device 10 may include an image production system that is configured to display virtual objects such as holograms to the user with the at least partially see-through display. The holograms may be visually superimposed onto the physical environment so as to be perceived at various depths and locations. The HMD device 10 may use stereoscopy to visually place a virtual object at a desired depth by displaying separate images of the virtual object to both of the user's eyes.

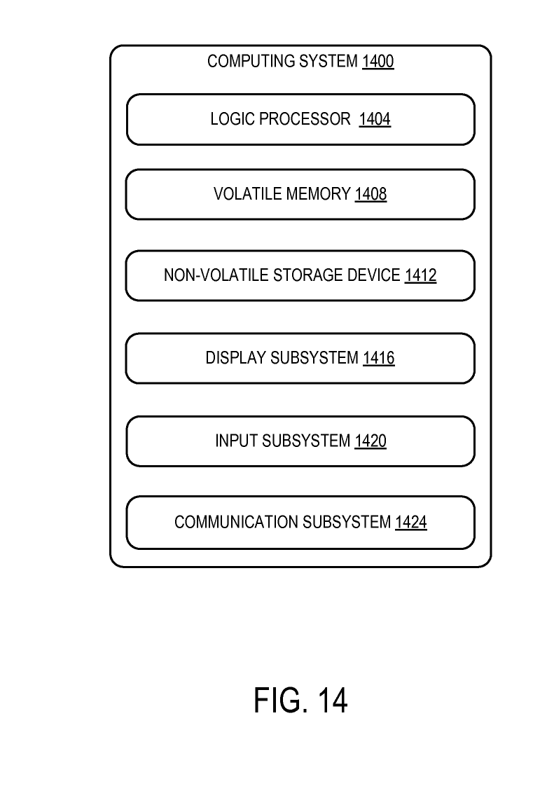

Computing device 20 may be communicatively coupled to HMD device 10. In some examples, computing device 20 may take the form of a server, networking computer, mobile communication device, desktop computer, laptop computer, tablet computer, or any other type of suitable computing device. In some examples, computing device 20 may comprise an embedded system within a larger electronic or mechanical device or system. For example, computing device 20 may be a component of HMD device 10. Additional details regarding the components and computing aspects of the computing device 20 are described in more detail below with respect to FIG. 14.

Computing device 20 may include a BIM management program 24 that may be stored in mass storage 28 of the computing device. The BIM management program 24 may be loaded into memory 34 and executed by a processor 40 of the computing device 20 to perform one or more of the methods and processes described in more detail below. As described in more detail below, mass storage 28 also may comprise a BIM database 30 containing BIM data 34 that comprise component records 38 of components contained in, planned for or otherwise related to a structure.

The computing device 20 may be communicatively coupled to one or more other devices via a wired connection or a wireless connection to a network. In some examples, the network may take the form of a local area network (LAN), wide area network (WAN), wired network, wireless network, personal area network, or a combination thereof, and may include the Internet.

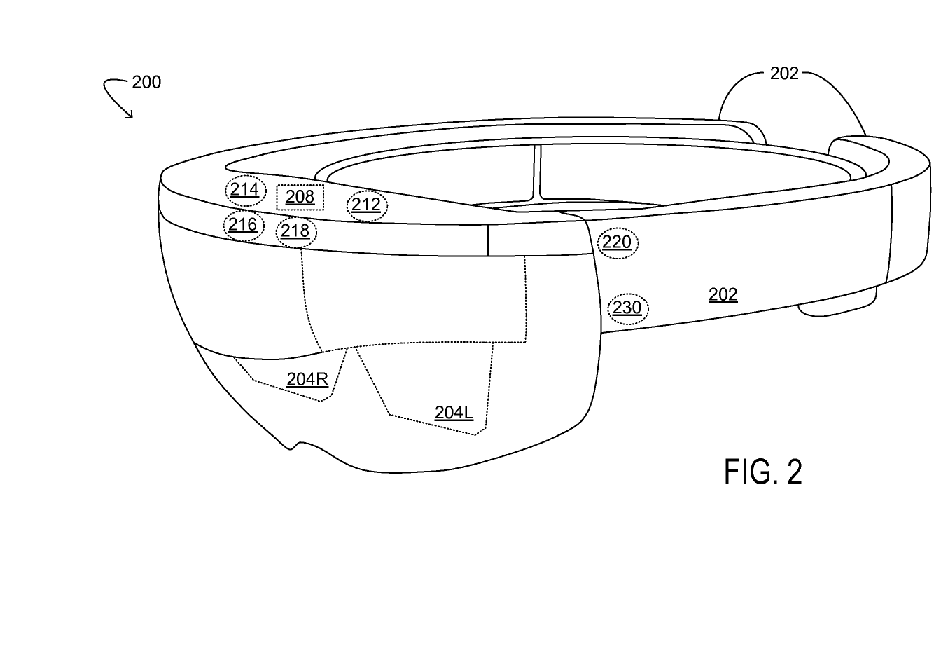

FIG. 2 shows aspects of an example HMD device 200 that may be worn by a user. For example, the HMD device 200 may be a non-limiting example of the HMD device 10 of FIG. 1. In other examples an HMD device may take any other suitable form in which an at least partially see-through display is supported in front of a viewer's eye or eyes.

In the example of FIG. 1, the HMD device 200 includes a frame 202 that wraps around the head of a user to position at least partially see-through right display panel 204R and at least partially see-through left display panel 204L close to the user's eyes. The frame supports additional stereoscopic, see-through display componentry as described in more detail below. HMD device 200 may be used in augmented-reality applications, where virtual display imagery is mixed with real-world imagery.

In this example HMD device 200 includes separate right and left display panels, 204R and 204L, which may be wholly or partially transparent from the perspective of the user, to give the user a clear view of his or her surroundings. A controller 208 is operatively coupled to the display panels 204R and 204L and to other display-system componentry. The controller 208 includes logic and associated computer memory configured to provide image signals to the display panels 204R and 204L, to receive sensory signals, and to enact various control processes described herein.

The display panels 204R and 204L facilitate the delivery of holographic images to the eyes of a wearer of the HMD device 200. In this manner, the display panels 204R and 204L may be configured to visually augment an appearance of a real-world, physical environment to a wearer viewing the physical environment through the panels.

Any suitable display technology and configuration may be used to display images via the at least partially see-through display panels 204R and 204L. For example, the panels may be configured to enable a wearer of the HMD device 200 to view a physical, real-world object in the physical environment through one or more partially transparent pixels that are displaying a virtual object representation. For example, the panels may include image-producing elements such as, for example, a see-through Organic Light-Emitting Diode (OLED) display.

As another example, the HMD device 200 may include a light modulator on an edge of the panels. In this example, the panels may serve as a light guide for delivering light from the light modulator to the eyes of a wearer. Such a light guide may enable a wearer to perceive a 3D holographic image located within the physical environment that the wearer is viewing, while also allowing the wearer to view physical objects in the physical environment, thus creating an augmented reality environment. In other examples, the display panels may utilize a liquid crystal on silicon (LCOS) display. Additionally, while the example of FIG. 2 shows separate right and left display panels 204R and 204L, a single display panel extending over both eyes may be used in other examples.

The HMD device 200 may also include various sensors and related systems to provide information to the controller 208. Such sensors may include, but are not limited to, one or more inward facing image sensors 212, 214, one or more outward facing image sensors 216, 218, an inertial measurement unit (IMU) 220, and one or more microphones 230. The one or more inward facing image sensors 212, 214 may be configured to acquire image data in the form of gaze tracking data from a wearer's eyes (e.g., sensor 212 may acquire image data from one of the wearer's eyes, and sensor 214 may acquire image data from the other of the wearer's eye).

The controller 208 may execute instructions to determine gaze directions of each of a wearer's eyes in any suitable manner based on the information received from the image sensors 212, 214. For example, one or more light sources, such as infrared light sources, may be configured to cause a glint of light to reflect from the cornea of each eye of a wearer. The one or more image sensors 212, 214 may be configured to capture an image of the wearer's eyes. Images of the glints and of the pupils as determined from image data gathered from the image sensors may be used to determine an optical axis of each eye.

Using this information, the controller 208 may execute instructions to determine a direction in which the wearer is gazing (also referred to as a gaze vector). The controller 208 also may execute instructions to determine a location at which the wearer is gazing and/or an identity of a physical and/or virtual object at which the wearer is gazing by projecting the user's gaze vector onto a 3D model of the surrounding environment. The one or more light sources and the one or more inward facing image sensors 212, 214 may collectively represent a gaze sensor configured to measure one or more gaze parameters of the user's eyes.

In other implementations, a different type of gaze sensor may be employed in the HMD device 200 to measure one or more gaze parameters of the user's eyes. Examples of gaze parameters measured by one or more gaze sensors may include an eye gaze direction or gaze vector, head orientation, eye gaze velocity, eye gaze acceleration, change in angle of eye gaze direction, and/or any other suitable tracking information. In some implementations, eye gaze tracking may be recorded independently for both eyes of the wearer of the HMD device 200.

The one or more outward facing image sensors 216, 218 may be configured to measure physical environment attributes of the physical environment in which the HMD device 200 is located (e.g., light intensity). In one example, image sensor 216 may include a visible-light camera configured to collect a visible-light image of a physical space. Further, the image sensor 218 may include a depth camera configured to collect a depth image of a physical space. More particularly, in one example the depth camera is an infrared time-of-flight depth camera. In another example, the depth camera is an infrared structured light depth camera.

Data from the outward facing image sensors 216, 218 may be used by the controller 208 to detect movements within a field of view of the HMD device 200, such as gesture-based inputs or other movements performed by a wearer or by a person or physical object within the field of view. In one example, data from the outward facing image sensors 216, 218 may be used to detect user input performed by the wearer of the HMD device 200, such as a gesture (e.g., a pinching of fingers, closing of a fist, pointing with a finger or hand, etc.), that indicates an action to be taken, a selection of a hologram or other virtual object displayed on the display device, or other command.

Data from the outward facing image sensors 216, 218 also may be used by the controller 208 to determine direction/location and orientation data (e.g., from imaging environmental features) that enables position/motion tracking of the HMD device 200 in the real-world environment. In some examples such position/motion tracking may be performed with respect to a real world object, such as a structure or portion of a structure. Data from the outward facing image sensors 216, 218 may be used by the controller 208 to construct still images and/or video images of the surrounding environment from the perspective of the HMD device 200.

Data from the outward facing image sensors 216, 218 may be used by the controller 208 to identify surfaces of a physical space. As such, the outward facing image sensors 216, 218 may be referred to as surface sensors configured to measure one or more surface parameters of the physical space.

The controller 208 may execute instructions to identify surfaces of the physical space in any suitable manner. In one example, surfaces of the physical space may be identified based on depth maps derived from depth data provide by the depth camera 218. In another example, the controller 208 may execute instructions to generate or update a three-dimensional model of the physical space using information from outward facing image sensors 216, 218.

Additionally or alternatively, information from outward facing image sensors 216, 218 may be communicated to a remote computer responsible for generating and/or updating a model of the physical space. In either case, the relative position and/or orientation of the HMD device 200 relative to the physical space may be assessed so that augmented-reality images may be accurately displayed in desired real-world locations with desired orientations. In one example, the augmented-reality engine may be configured to perform simultaneous localization and mapping (SLAM) of a physical space using information provided by a surface sensor, alone or in combination with other sensors of the HMD device 200. In particular, the controller 208 may execute instructions to generate a 3D model of the physical space including surface reconstruction information that may be used to identify surfaces in the physical space.

The IMU 220 may be configured to provide position and/or orientation data of the HMD device 200 to the controller 208. In one implementation, the IMU 220 may be configured as a three-axis or three-degree of freedom (3DOF) position sensor system. This example position sensor system may, for example, include three gyroscopes to indicate or measure a change in orientation of the HMD 220 within 3D space about three orthogonal axes (e.g., roll, pitch, and yaw). The orientation derived from the sensor signals of the IMU may be used to display, via the see-through display, one or more holographic images with a realistic and stable position and orientation.

In another example, the IMU 220 may be configured as a six-axis or six-degree of freedom (6DOF) position sensor system. Such a configuration may include three accelerometers and three gyroscopes to indicate or measure a change in location of the HMD device 200 along three orthogonal spatial axes (e.g., x, y, and z) and a change in device orientation about three orthogonal rotation axes (e.g., yaw, pitch, and roll). In some implementations, position and orientation data from the outward facing image sensors 216, 218 and the IMU 220 may be used in conjunction to determine a position and orientation (or 6DOF pose) of the HMD device 200.

In some examples, a 6DOF position sensor system may be used to display holographic representations in a world-locked manner. A world-locked holographic representation appears to be fixed relative to real-world objects viewable through the HMD device 200, and the world-locked position of each virtual object appears to be moveable relative to a wearer of the HMD device 200.

In other examples, the HMD device 200 may operate in a body-lock display mode in which one or more holographic objects may be displayed via the HMD device with body-locked positions. In a body-locked position, a holographic object appears to be fixed relative to the wearer of the HMD device 200, and the body-locked position of the holographic object appears to be moveable relative to real-world objects.

Optical sensor information received from the outward facing image sensors 216, 218 and/or position sensor information received from IMU 220 may be used to assess a position and orientation of the vantage point of the HMD device 200 relative to other environmental objects. In some embodiments, the position and orientation of the vantage point may be characterized with six degrees of freedom (e.g., world-space X, Y, Z, pitch, roll, yaw). The vantage point may be characterized globally or independent of the real world background.

The HMD device 200 may also support other suitable positioning techniques, such as GPS or other global navigation systems. Further, while specific examples of position sensor systems have been described, it will be appreciated that any other suitable sensor systems may be used. For example, head position or pose and/or movement data may be determined based on sensor information from any combination of sensors mounted on the HMD device 200 and/or external to the device including, but not limited to, any number of gyroscopes, accelerometers, inertial measurement units, GPS devices, barometers, magnetometers, cameras (e.g., visible light cameras, infrared light cameras, time-of-flight depth cameras, structured light depth cameras, etc.), communication devices (e.g., WIFI antennas/interfaces), etc.

The controller 208 may include a logic processor, volatile memory and non-volatile storage as discussed in more detail below with respect to FIG. 14, in communication with the at least partially see-through panels and the various sensors of the HMD device 200.

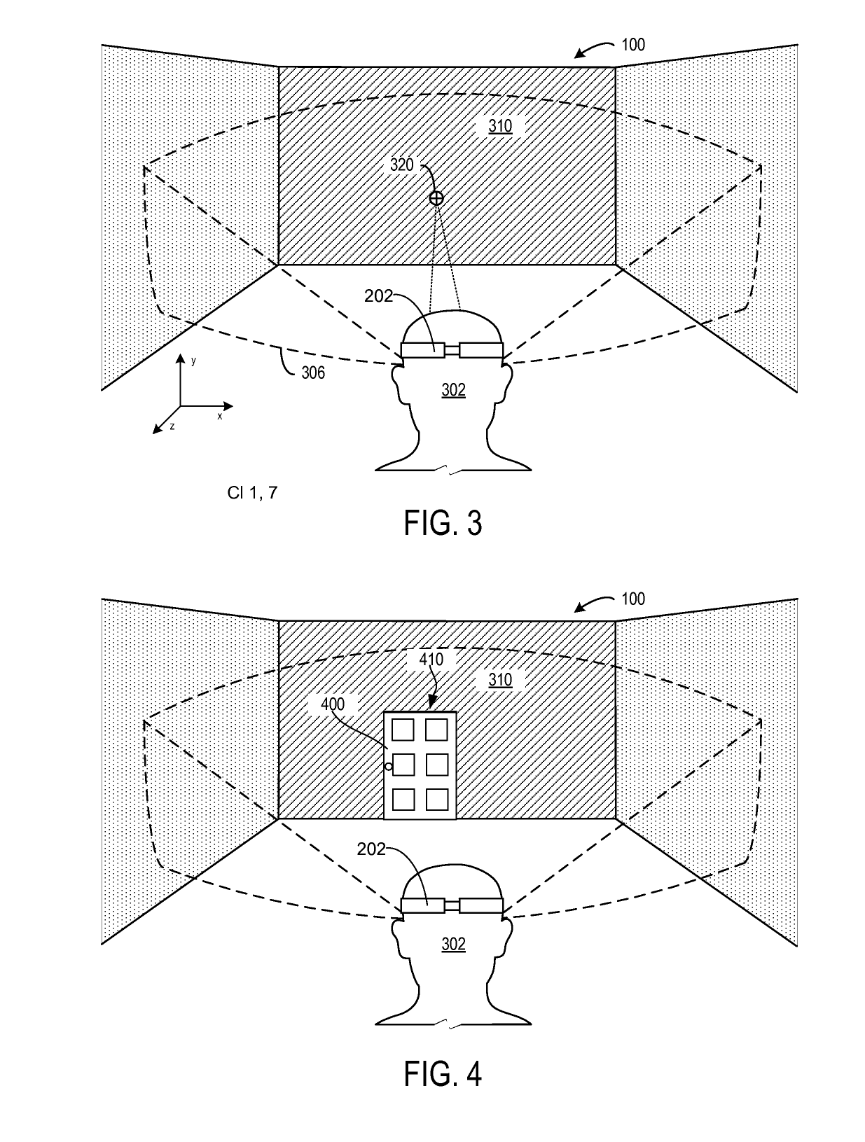

With reference now to FIGS. 3-12, example use cases illustrating aspects of the present disclosure will now be presented. As schematically shown in FIG. 3, a user 302 may be standing in or near a structure 100 and may wear the HMD device 200 as shown in FIG. 2 and described above. As noted above, HMD device 200 may comprise an at least partially see-through display configured to visually augment the view of user 302 through the display of the real world three dimensional environment of the structure 100. In some examples, the HMD device 200 may provide the user 302 with a field of view 306 of the structure 100.

In some examples the HMD device 200 may generate a virtual model of the structure 100 using a three dimensional coordinate space overlaid upon the real world structure. In the example of FIG. 3, such three dimensional coordinate space is indicated by the x-y-z axes.

With reference again to FIG. 1 and as noted above, the HMD device 200 may be communicatively coupled to a computing device that comprises a BIM management program 24 and a BIM database 30. The BIM database 30 may store BIM data 34 comprising digital representations of physical and functional features and characteristics of a structure, such as a building or a facility. In some examples the BIM data 34 may include component records 38 of components contained in, planned for or otherwise related to a structure.

With reference again to the example of FIG. 3, in one example user 302 may desire to see structural changes that are planned for a surface of the structure 100, such as wall 310. For example, a door may be planned to be installed in the wall 310. User 302 may have previously viewed blueprints or other documents that show the location of the proposed door in wall 310. However, viewing such documents provided the user 302 with a limited understanding and a mere 2 dimensional schematic representation of the proposed door in relation to wall 310. In some examples, the user 302 may not recall the location of the proposed door.

Even if the user 302 has documents in hand or access to a 2 dimensional screen that displays the documents, the user's ability to visualize the proposed door in the wall 310 via such documentation or separate screen is limited. Additionally, the blueprints or other separate documentation force the user 302 to imagine the appearance of the door in the wall 310. Further, such documentation provides a very limited visual appreciation of the proposed door in context with other portions of the structure 100, such as portions of the structure that are otherwise hidden from view by the surface 310.

Accordingly and in one example, the user 302 may provide user input to HMD device 200 to display structural changes planned for the wall 310. User 302 may provide user input to the HMD device 200 via gestures performed by the user, such as movements of the user's finger(s), hand(s), head, or other body part, via voice commands that are interpreted using voice recognition, or any other suitable user input mechanism or technique. In response to the user input, the HMD device 200 may access the BIM database 214 to identify structural changes that are planned for the wall 310.

In one example, HMD device 200 may track a position and orientation of the device with respect to structure 100, and may determine that the user 302 is facing the wall 310. In some examples, HMD device 200 may track the gaze location of user 302 as described above to determine that the user is gazing at location 320 on the wall 310. In some examples, HMD device 200 may track both user gaze location and a position and orientation of HMD device 200. HMD device 200 may utilize surface reconstruction to identify the wall 310 of the structure 100.

In one example, the HMD device 200 may determine from the BIM data 34 that a door is planned to be installed in wall 310. The HMD device 200 may access component records 38 and retrieve data describing the door and its location in the wall 310. Using such data and with reference to FIG. 4, the HMD device may display a world-locked holographic representation of the door 400 in the location 410 at which it is planned to be installed.

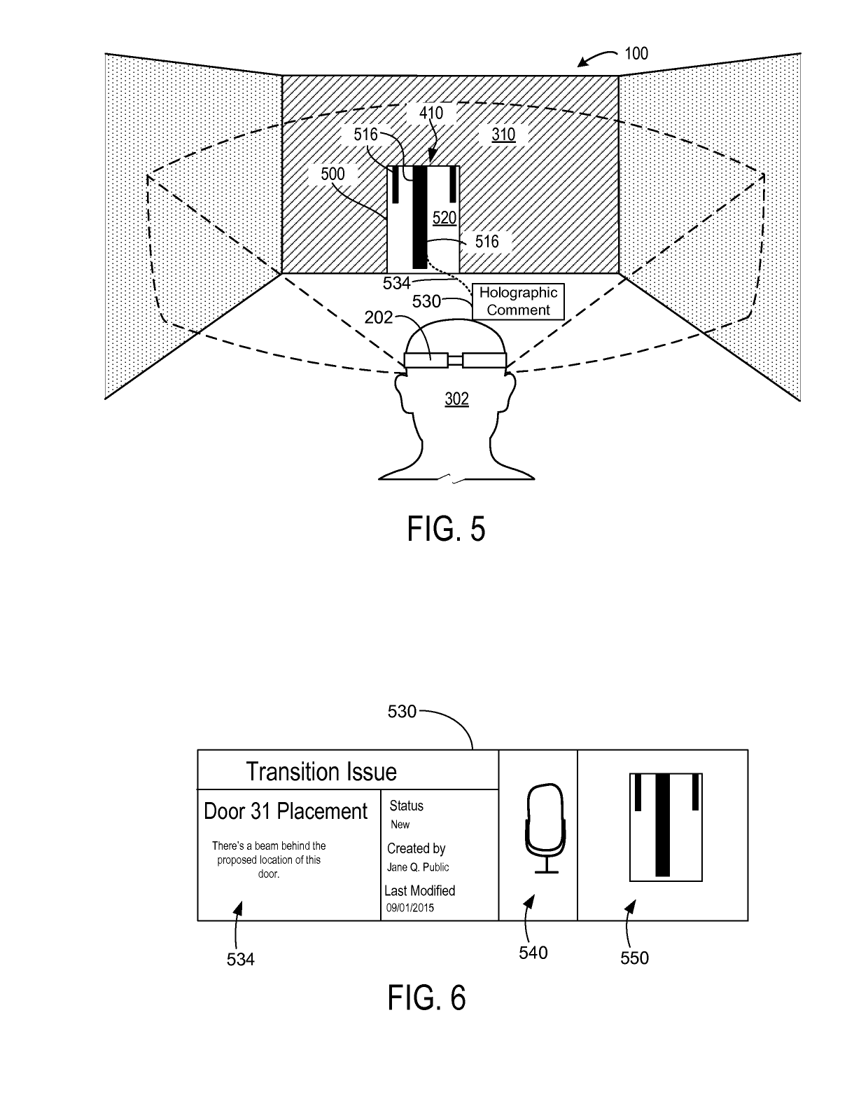

In one example, user 302 may desire to see one or more portions of the structure 100 that are hidden from the user's view. For example, the user 302 may desire to see the portions of the structure 100 that are located behind the wall 310 at the proposed location 410 of the door 400. Examples of such portions of the structure 100 that may be hidden from the user's view may include beams, fixtures, other structural elements, plumbing components behind or within wall 310, electrical components behind or within wall 310, etc. In one example and with reference to FIG. 5, the user 302 may provide a portal user input to the HMD device 200 to cause the device to display a world-locked holographic portal 500 on the wall 310 of structure 100.

The world-locked holographic portal 500 may comprise a world-locked holographic representation of a portion of the structure 100 that is otherwise hidden from view by the wall 310. In the example of FIG. 5, the portion of the structure 100 displayed in holographic portal 500 includes support columns 516 in a room 520 located behind the wall 310. In some examples, the HMD device 200 may obtain BIM data 34 regarding the support columns 516 from as-built records corresponding to elements of the structure 100 that have been constructed. In other examples, the HMD device 200 may obtain BIM data 34 regarding the support columns 516 from planning documents corresponding to elements of the structure that are planned to be constructed.

In one example and as shown in FIG. 5, the holographic portal 500 may reveal to the user 302 that one of the support columns 516 is located directly behind the proposed location 410 of door 400. The user 302 may desire to make a record that documents the location of this support column behind the proposed location 410 of the door 400. In some examples, the user 302 may generate via the HMD device 100 a holographic comment 530 regarding the structure 100 that may be geo-located with the holographic portal 500. In the example of FIG. 5, the holographic comment 530 includes a connector 534 that visually associates the comment with one of the holographic support columns 516.

In some examples, a holographic comment may comprise one or more of text, audio commentary from a user, one or more images of the holographic representation of a portion of the structure otherwise hidden from view, and a timestamp of the comment. FIG. 6 illustrates one example of a holographic comment 530. In this example, the comment may include a Subject “Transition Issue”, a text box 534 containing text describing the comment, a Status portion, a portion indicating the person who created the comment, and a timestamp indicating when the comment was last modified. The holographic comment 530 also may include audio commentary from a user, indicated by the microphone icon 540 that may be selected to play the audio commentary via speakers on the HMD device 200. The holographic comment 530 also may include an image 550 of the beams 516 that are otherwise hidden from view of the user.

Once generated, the geo-located holographic comment 530 may be added to the BIM database 30 for easy location and retrieval by other parties.

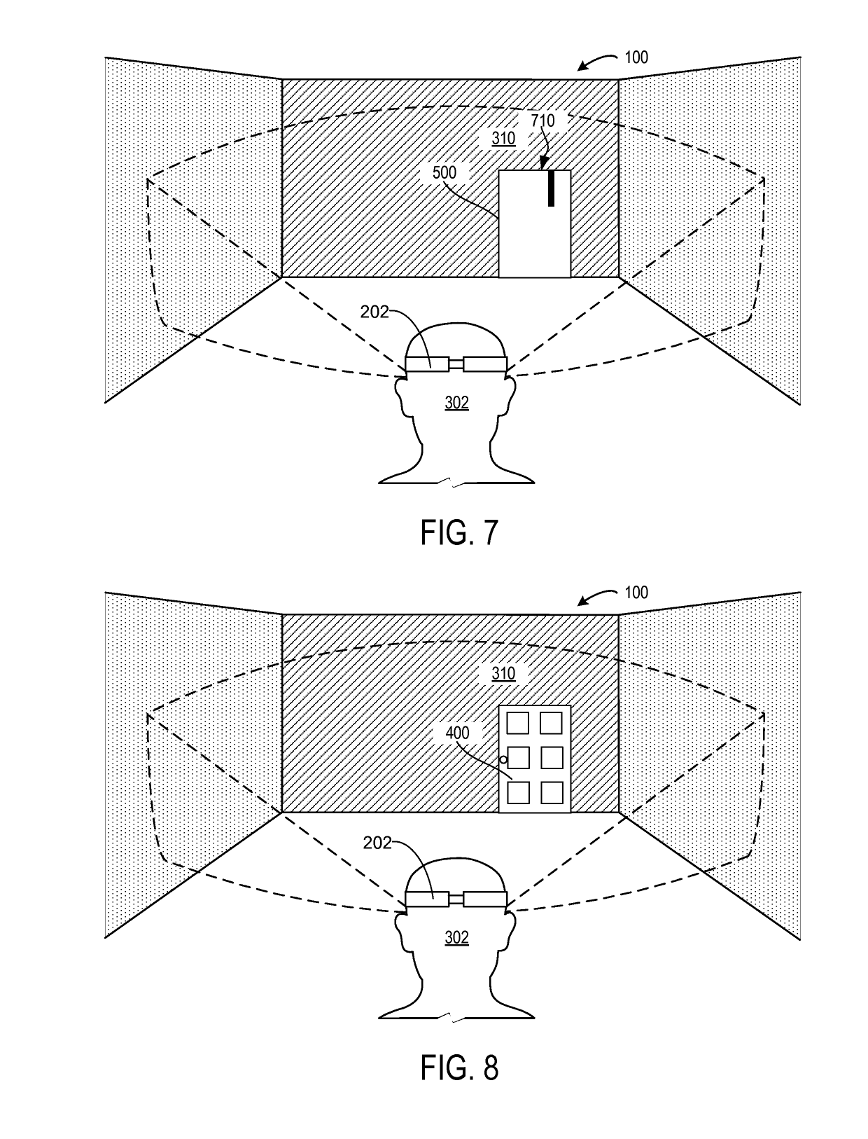

In some examples the user 302 may provide an operation user input to cause the HMD device 200 to perform a virtual operation on the structure 100. Based on the virtual operation, the HMD device 200 may update the BIM database 30. In some examples, the virtual alteration may comprise virtually altering a physical feature of the structure 100. With reference now to FIG. 7, in one example and after seeing the beam 516 located behind the proposed location 410 of the door 400, the user 302 may provide an operation user input to move the location of the door from proposed location 410 to revised location 710.

In this example, the virtual portal 500 is moved to revised location 710. Once the user 302 finalizes the revised location 710, the BIM database 30 may be updated to reflect the revised location of the door 400. With reference to FIG. 8, the holographic representation of the door 400 then may be displayed at the revised location 710. In this manner, a virtual component selected from the BIM data 34 may be added to the structure 100.

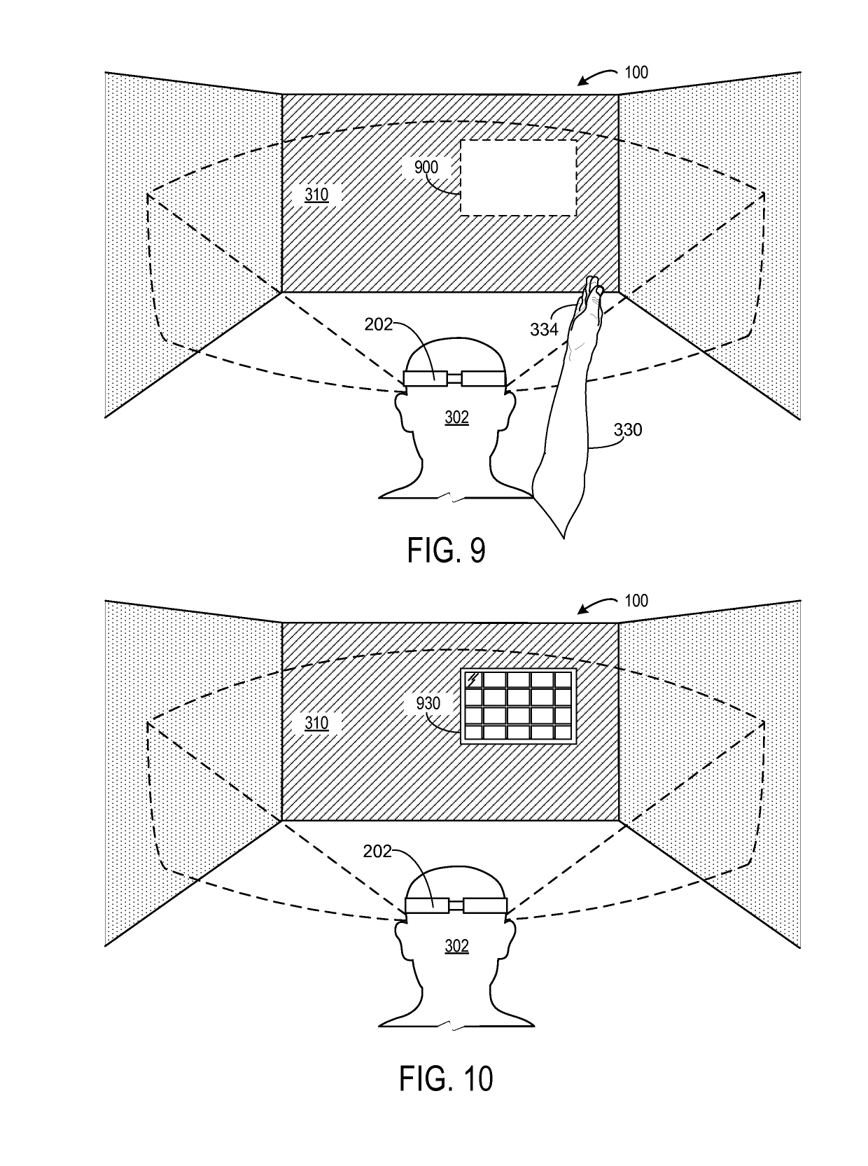

With reference now to FIG. 9, in some examples the user 302 may desire to install a component on wall 310. The component may be selected from component records 38 of the building information data 34 of the BIM database 30. The user 302 may provide user input to the HMD device 200 to cause the device to display on the wall 310 a world-locked holographic installation template 900 having installation dimensions corresponding to the actual component selected from the building information data of the BIM database.

For example, user 302 may desire to install a window on wall 310. In some examples, the user 302 may provide voice input to HMD device 200 that identifies the desired window to be installed. In response and utilizing component records 38 corresponding to the window component from the BIM data 34 in BIM database 30, the BIM management program 24 may identify the corresponding window component and corresponding holographic installation template 900 in the component records 38.

As shown in FIG. 9, in one example the user 302 may gesture with the user's right arm 330 and hand 334 to cause the HMD device 200 to display on the wall 310 the world-locked holographic installation template 900. The installation template 900 may have installation dimensions corresponding to the actual window to be installed. In this manner for example, the user 302 may easily view on the actual wall 310 the precise locations of cuts to be made into the wall to install the actual window. In some examples, a holographic representation of the actual window may be displayed within the holographic template 900.

With the reference now to FIG. 10, in one example the user 302 has installed the actual window 930 in wall 310 according to the holographic installation template 900. In some examples, the HMD device 200 may capture one or more of depth data and image data of the actual window 930 as installed in the structure 100. The HMD device 200 then may add one or more of the depth data and the image data to the BIM database 30. For example, the HMD device 200 may update an as-built document that reflects a current as-built status of the structure 100. In this manner, the HMD device 200 may generate real-time updates of, for example, as-built records in the BIM database 30 that reflect newly added or revised components of the structure 100. Additionally and in some examples, one or more of the depth data and image data may be tagged in the BIM database 30 with a component location of the actual window 930 as installed in the structure 100. In this manner, the newly added window 930 may be associated with its precise location in the structure 100.

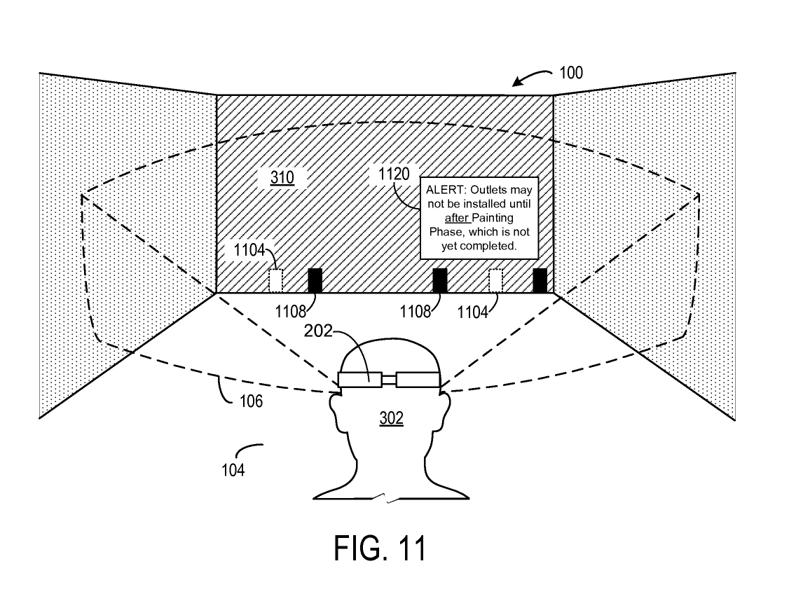

With reference now to FIG. 11, in some examples the user 302 may desire to know where one or more components may be installed on wall 301, or where other modifications may be made on the wall. For example, the user 302 may desire to know potential locations for electrical outlets in wall 310. The user 302 may provide corresponding user input to HMD device 200, such as a vocal request “Show me the eligible and ineligible locations for electrical outlets on this wall.”

In response and utilizing component records 38 corresponding to the wall 310 and associated other records such as wiring diagrams from the BIM data 34, the BIM management program 24 may identify eligible and ineligible locations for electrical outlets in wall 310. The HMD device 200 may receive this data and may display corresponding world-locked holographic eligible locations 1104 where an outlet may be installed. In some examples, the HMD device 200 also may display world-locked holographic ineligible locations 1108 where outlets may not be installed.

In some examples the HMD device 200 and/or the BIM management program 24 may determine that a virtual operation relates to an event. For example, in the example of FIG. 11 the BIM management program 24 may access project schedule documentation related to structure 100 and determine that a painting phase is required to occur before electrical outlets may be installed in wall 310. The BIM management program 24 also may determine that such painting phase has not yet been completed. Using this data and based on the determination, a timing alert may be communicated to the user 302 that associates the installation of electrical outlets with the painting phase. More particularly and in one example shown in FIG. 11, a holographic Alert 1120 may be displayed to user 302 that informs the user that outlets may not be installed until after the painting phase, which has not yet been completed. In other examples, timing alerts may be communicated to user 302 via audio messages, video messages, and any other suitable communication media.

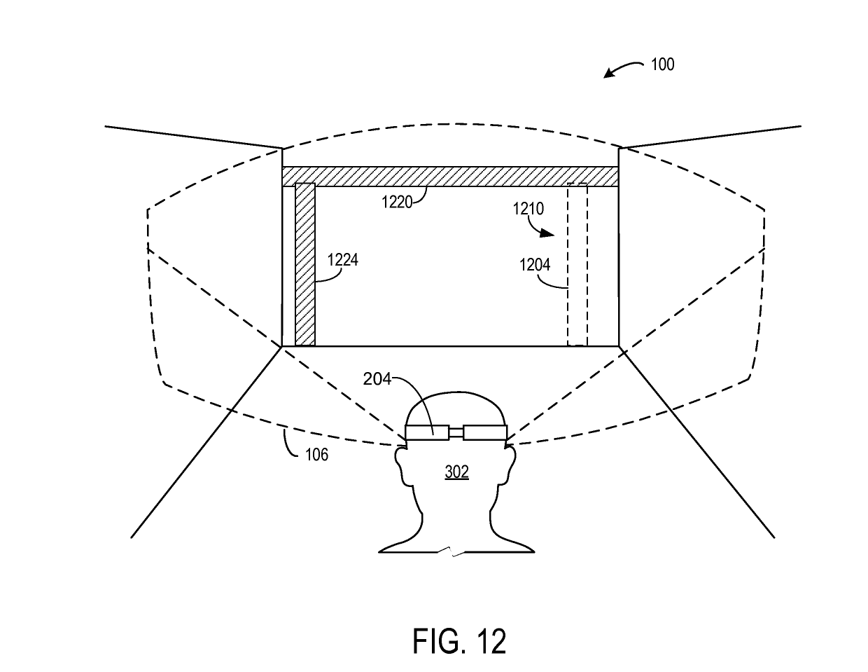

In some examples the user 302 may desire to evaluate one or more proposed additions or other modifications to the structure 100. For example and with reference to FIG. 12, the user 302 may desire to evaluate different placements of a load-bearing component, such as a beam. In response to user input, the HMD device 200 may display a world-locked holographic representation of a virtual load-bearing beam 1204 at a proposed location 1210 in the structure 100.

The virtual load-bearing beam 1204 may correspond to an actual load-bearing beam that embodies one or more characteristics, such as dimensions of the beam, an allowable fiber stress for wooden beams, etc. Based on the proposed location 1210 of the virtual load-bearing beam 1204, and utilizing relevant characteristics of the corresponding actual beam, the BIM management program 24 may perform or update a load calculation for the virtual load-bearing beam 1204.

For example, the BIM management program 24 may access BIM data 34 regarding the location and structural and material characteristics of existing beams 1220 and 1224, as well as the structural and material characteristics of the actual beam corresponding to the virtual load-bearing beam 1204. Using this data along with the proposed location 120 of the virtual load-bearing beam 1204, the BIM management program 24 may perform one or more load calculations, such as a maximum bending moment of the actual beam corresponding to the virtual load-bearing beam 1204, the section modulus of the beam, etc.

The HMD device 200 may receive the load calculation(s) for the load-bearing beam 1204 from the BIM management program 24. In some examples, such updated load calculation(s) may be displayed by the HMD device 200 to the user 302. In some examples, such as upon user confirmation of the proposed location for the virtual load-bearing beam 1204, the HMD device 200 may update the BIM database 30 with the calculation.

It will be appreciated that many other types of virtual components in proposed locations may be displayed, such as electrical components, plumbing components, HVAC components, etc., and that corresponding load calculations and/or other calculations may be performed with respect to such other virtual components.

It also will be appreciated that the foregoing examples are provided for illustrative purposes, and that the principles of the present disclosure may be utilized with various other use cases and in various other contexts.

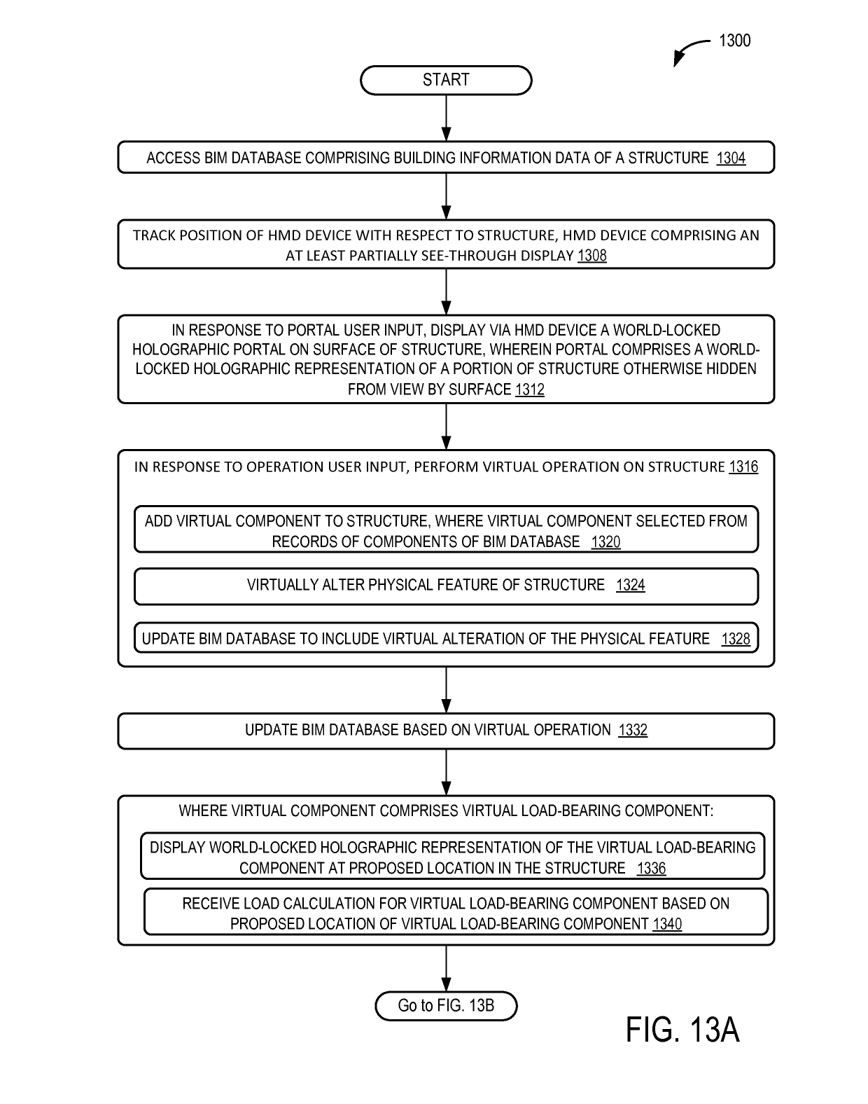

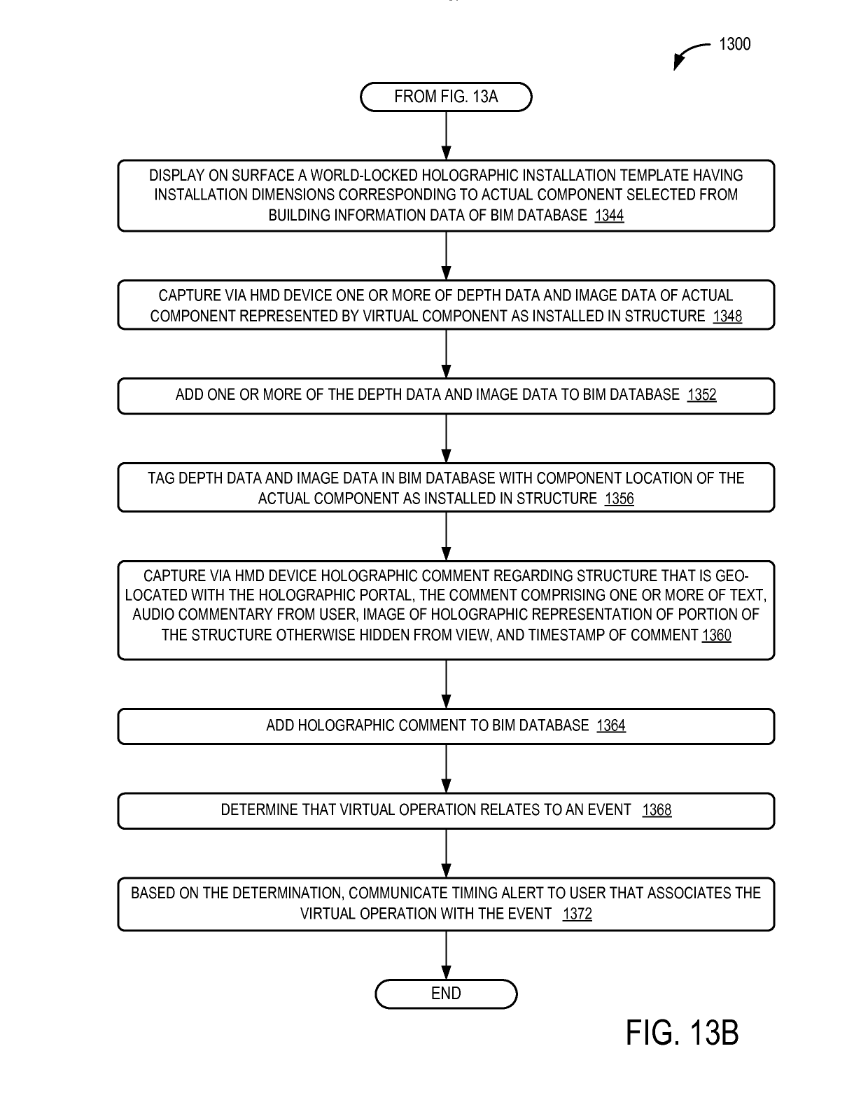

FIGS. 13A and 13B illustrate a flow chart of a method 1300 for updating a BIM database according to an example of the present disclosure. The following description of method 1300 is provided with reference to the software and hardware components described above and shown in FIGS. 1-12. It will be appreciated that method 1300 also may be performed in other contexts using other suitable hardware and software components.

With reference to FIG. 13A, at 1304 the method 1300 may include accessing a building information modeling database comprising building information data of a structure. At 1308 the method 1300 may include tracking a position of a head-mounted display device with respect to the structure, the head-mounted display device comprising an at least partially see-through display. At 1312 the method 1300 may include, in response to a portal user input, displaying via the head-mounted display device a world-locked holographic portal on a surface of the structure, wherein the portal comprises a world-locked holographic representation of a portion of the structure otherwise hidden from view by the surface.

At 1316 the method 1300 may include, in response to an operation user input, performing a virtual operation on the structure. At 1320 performing the virtual operation may include adding a virtual component to the structure, wherein the virtual component is selected from the building information data of the building information modeling database. At 1324 performing the virtual operation may include virtually altering a physical feature of the structure. At 1328 the method 1300 may include updating the building information modeling database to include the virtual alteration of the physical feature.

At 1332 the method 1300 may include updating the building information modeling database based on the virtual operation. At 1336, where the virtual component comprises a virtual load-bearing component, the method 1300 may include displaying a world-locked holographic representation of the virtual load-bearing component at a proposed location in the structure. At 1340 the method 1300 may include receiving a load calculation for the virtual load-bearing component that is based on the proposed location of the virtual load-bearing component.

With reference to FIG. 13B, at 1344 the method 1300 may include displaying on the surface a world-locked holographic installation template having installation dimensions corresponding to an actual component selected from the building information data of the building information modeling database. At 1348 the method 1300 may include capturing via the head-mounted display device one or more of depth data and image data of an actual component represented by the virtual component as installed in the structure. At 1352 the method 1300 may include adding one or more of the depth data and the image data to the building information modeling database.

At 1356 the method 1300 may include tagging the depth data and the image data in the building information modeling database with a component location of the actual component as installed in the structure. At 1360 the method 1300 may include capturing via the head-mounted display device a holographic comment regarding the structure that is geo-located with the holographic portal, the comment comprising one or more of text, audio commentary from a user, an image of the holographic representation of the portion of the structure otherwise hidden from view, and a timestamp of the comment. At 1364 the method 1300 may include adding the holographic comment to the building information modeling database.

At 1368 the method 1300 may include determining that the virtual operation relates to an event. At 1372 the method 1300 may include, based on the determination, communicating a timing alert to a user that associates the virtual operation with the event.

It will be appreciated that method 1300 is provided by way of example and is not meant to be limiting. Therefore, it is to be understood that method 1300 may include additional and/or alternative steps relative to those illustrated in FIGS. 13A and 13B. Further, it is to be understood that method 1300 may be performed in any suitable order. Further still, it is to be understood that one or more steps may be omitted from method 1300 without departing from the scope of this disclosure.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 14 schematically shows a non-limiting embodiment of a computing system 1400 that can enact one or more of the methods and processes described above. Computing system 1400 is shown in simplified form. Computing system 1400 may take the form of one or more HMD devices as shown in FIGS. 1 and 2, or one or more devices cooperating with a head-mounted display device (e.g., personal computers, server computers, tablet computers, home-entertainment computers, network computing devices, gaming devices, mobile computing devices, mobile communication devices (e.g., smart phone), and/or other computing devices).

Computing system 1400 includes a logic processor 1404, volatile memory 1408, and a non-volatile storage device 1412. Computing system 1400 may optionally include a display subsystem 1416, input subsystem 1420, communication subsystem 1424, and/or other components not shown in FIG. 14.

Logic processor 1404 includes one or more physical devices configured to execute instructions. For example, the logic processor may be configured to execute instructions that are part of one or more applications, programs, routines, libraries, objects, components, data structures, or other logical constructs. Such instructions may be implemented to perform a task, implement a data type, transform the state of one or more components, achieve a technical effect, or otherwise arrive at a desired result.

The logic processor may include one or more physical processors (hardware) configured to execute software instructions. Additionally or alternatively, the logic processor may include one or more hardware logic circuits or firmware devices configured to execute hardware-implemented logic or firmware instructions. Processors of the logic processor 1404 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects may be run on different physical logic processors of various different machines.

Volatile memory 1408 may include physical devices that include random access memory. Volatile memory 1408 is typically utilized by logic processor 1404 to temporarily store information during processing of software instructions. It will be appreciated that volatile memory 1408 typically does not continue to store instructions when power is cut to the volatile memory 1408.

Non-volatile storage device 1412 includes one or more physical devices configured to hold instructions executable by the logic processors to implement the methods and processes described herein. When such methods and processes are implemented, the state of non-volatile storage device 1412 may be transformed—e.g., to hold different data.

Non-volatile storage device 1412 may include physical devices that are removable and/or built-in. Non-volatile storage device 1412 may include optical memory (e.g., CD, DVD, HD-DVD, Blu-Ray Disc, etc.), semiconductor memory (e.g., ROM, EPROM, EEPROM, FLASH memory, etc.), and/or magnetic memory (e.g., hard-disk drive, floppy-disk drive, tape drive, MRAM, etc.), or other mass storage device technology. Non-volatile storage device 1412 may include nonvolatile, dynamic, static, read/write, read-only, sequential-access, location-addressable, file-addressable, and/or content-addressable devices. It will be appreciated that non-volatile storage device 1412 is configured to hold instructions even when power is cut to the non-volatile storage device 1412.

Aspects of logic processor 1404, volatile memory 1408, and non-volatile storage device 1412 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The term “program” may be used to describe an aspect of computing system 1400 implemented to perform a particular function. In some cases, a program may be instantiated via logic processor 1404 executing instructions held by non-volatile storage device 1412, using portions of volatile memory 1408. It will be understood that different programs may be instantiated from the same application, service, code block, object, library, routine, API, function, etc. Likewise, the same program may be instantiated by different applications, services, code blocks, objects, routines, APIs, functions, etc. The term “program” encompasses individual or groups of executable files, data files, libraries, drivers, scripts, database records, etc.

When included, display subsystem 1416 may be used to present a visual representation of data held by non-volatile storage device 1412. As the herein described methods and processes change the data held by the non-volatile storage device, and thus transform the state of the non-volatile storage device, the state of display subsystem 1416 may likewise be transformed to visually represent changes in the underlying data. Display subsystem 1416 may include one or more display devices utilizing virtually any type of technology. Such display devices may be combined with logic processor 1404, volatile memory 1408, and/or non-volatile storage device 1412 in a shared enclosure, or such display devices may be peripheral display devices. The at least partially see-through panels 204R and 204L of HMD device 200 configured to display virtual objects such as holograms using display technologies described above are one example of a display subsystem 1416.

When included, input subsystem 1420 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection, gaze detection, and/or intent recognition, as well as electric-field sensing componentry for assessing brain activity, and/or any other suitable sensor.

When included, communication subsystem 1424 may be configured to communicatively couple computing system 1400 with one or more other computing devices. Communication subsystem 1424 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 1400 to send and/or receive messages to and/or from other devices via a network such as the Internet.

The following paragraphs provide additional support for the claims of the subject application. One aspect provides a head-mounted display device, comprising: a camera configured to capture images; an at least partially see-through display; a processor; and a memory holding instructions executable by the processor to: access a building information modeling database comprising building information data of a structure; track a position of the head-mounted display device with respect to the structure; in response to a portal user input, display a world-locked holographic portal on a surface of the structure, wherein the portal comprises a world-locked holographic representation of a portion of the structure otherwise hidden from view by the surface; in response to an operation user input, perform a virtual operation on the structure; and update the building information modeling database based on the virtual operation. The head-mounted display device may additionally or optionally include, wherein the virtual operation comprises adding a virtual component to the structure, wherein the virtual component is selected from the building information data of the building information modeling database. The head-mounted display device may additionally or optionally include, wherein the virtual component comprises a virtual load-bearing component, the instructions executable by the processor to: display a world-locked holographic representation of the virtual load-bearing component at a proposed location in the structure; and based on the proposed location of the virtual load-bearing component, receive a load calculation for the virtual load-bearing component. The head-mounted display device may additionally or optionally include, the instructions executable by the processor to display on the surface a world-locked holographic installation template having installation dimensions corresponding to an actual component selected from the building information data of the building information modeling database. The head-mounted display device may additionally or optionally include, the instructions executable by the processor to: capture one or more of depth data and image data of an actual component represented by the virtual component as installed in the structure; and add one or more of the depth data and the image data to the building information modeling database. The head-mounted display device may additionally or optionally include, wherein one or more of the depth data and the image data are tagged in the building information modeling database with a component location of the actual component as installed in the structure. The head-mounted display device may additionally or optionally include, the instructions executable by the processor to: generate a holographic comment regarding the structure that is geo-located with the holographic portal, the comment comprising one or more of text, audio commentary from a user, an image of the holographic representation of the portion of the structure otherwise hidden from view, and a timestamp of the comment; and add the holographic comment to the building information modeling database. The head-mounted display device may additionally or optionally include, wherein the virtual operation comprises virtually altering a physical feature of the structure, and the instructions executable by the processor to update the building information modeling database to include the virtual alteration of the physical feature. The head-mounted display device may additionally or optionally include, the instructions executable by the processor to display one or more of a world-locked holographic eligible location where the virtual operation may be performed and a world-locked holographic ineligible location where the virtual operation may not be performed. The head-mounted display device may additionally or optionally include, the instructions executable by the processor to: determine that the virtual operation relates to an event; and based on the determination, communicate a timing alert to a user that associates the virtual operation with the event.

Another aspect provides a method, comprising: accessing a building information modeling database comprising building information data of a structure; tracking a position of a head-mounted display device with respect to the structure, the head-mounted display device comprising an at least partially see-through display; in response to a portal user input, displaying via the head-mounted display device a world-locked holographic portal on a surface of the structure, wherein the portal comprises a world-locked holographic representation of a portion of the structure otherwise hidden from view by the surface; in response to an operation user input, performing a virtual operation on the structure; and updating the building information modeling database based on the virtual operation. The method may additionally or optionally include, wherein performing the operation comprises adding a virtual component to the structure, wherein the virtual component is selected from the building information data of the building information modeling database. The method may additionally or optionally include, wherein the virtual component comprises a virtual load-bearing component, the method further comprising: displaying a world-locked holographic representation of the virtual load-bearing component at a proposed location in the structure; and receiving a load calculation for the virtual load-bearing component that is based on the proposed location of the virtual load-bearing component. The method may additionally or optionally include displaying on the surface a world-locked holographic installation template having installation dimensions corresponding to an actual component selected from the building information data of the building information modeling database. The method may additionally or optionally include capturing via the head-mounted display device one or more of depth data and image data of an actual component represented by the virtual component as installed in the structure; and adding one or more of the depth data and the image data to the building information modeling database. The method may additionally or optionally include tagging the depth data and the image data in the building information modeling database with a component location of the actual component as installed in the structure. The method may additionally or optionally include capturing via the head-mounted display device a holographic comment regarding the structure that is geo-located with the holographic portal, the comment comprising one or more of text, audio commentary from a user, an image of the holographic representation of the portion of the structure otherwise hidden from view, and a timestamp of the comment; and adding the holographic comment to the building information modeling database. The method may additionally or optionally include, wherein performing the virtual operation comprises: virtually altering a physical feature of the structure; and updating the building information modeling database to include the virtual alteration of the physical feature. The method may additionally or optionally include determining that the virtual operation relates to an event; and based on the determination, communicating a timing alert to a user that associates the virtual operation with the event.

Another aspect provides head-mounted display device, comprising: a camera configured to capture images; an at least partially see-through display; a processor; and a memory holding instructions executable by the processor to: access a building information modeling database comprising building information data of a structure; track a position of the head-mounted display device with respect to the structure; in response to user input, display a world-locked holographic component at a proposed location in the structure, wherein the world-locked holographic component corresponds to an actual component that embodies a characteristic; receive a calculation that is based on the proposed location of the holographic component and the characteristic; and update the building information modeling database with the calculation.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A head-mounted display device, comprising:
a camera configured to capture images;
an at least partially see-through display;
a processor; and
a memory holding instructions executable by the processor to:
access a building information modeling database comprising building information data of a structure;
track a position of the head-mounted display device with respect to the structure;
in response to a portal user input, display a world-locked holographic portal on a surface of the structure, wherein the portal comprises a world-locked holographic representation of a portion of the structure otherwise hidden from view by the surface;
in response to an operation user input, perform a virtual operation on the structure; and
update the building information modeling database based on the virtual operation.

2. The head-mounted display device of claim 1, wherein the virtual operation comprises adding a virtual component to the structure, wherein the virtual component is selected from the building information data of the building information modeling database.

3. The head-mounted display device of claim 2, wherein the virtual component comprises a virtual load-bearing component, the instructions executable by the processor to:
display a world-locked holographic representation of the virtual load-bearing component at a proposed location in the structure; and
based on the proposed location of the virtual load-bearing component, receive a load calculation for the virtual load-bearing component.

4. The head-mounted display device of claim 1, the instructions executable by the processor to display on the surface a world-locked holographic installation template having installation dimensions corresponding to an actual component selected from the building information data of the building information modeling database.

5. The head-mounted display device of claim 2, the instructions executable by the processor to:
capture one or more of depth data and image data of an actual component represented by the virtual component as installed in the structure; and
add one or more of the depth data and the image data to the building information modeling database.

6. The head-mounted display device of claim 5, wherein one or more of the depth data and the image data are tagged in the building information modeling database with a component location of the actual component as installed in the structure.

7. The head-mounted display device of claim 1, the instructions executable by the processor to:
generate a holographic comment regarding the structure that is geo-located with the holographic portal, the comment comprising one or more of text, audio commentary from a user, an image of the holographic representation of the portion of the structure otherwise hidden from view, and a timestamp of the comment; and
add the holographic comment to the building information modeling database.

8. The head-mounted display device of claim 1, wherein the virtual operation comprises virtually altering a physical feature of the structure, and the instructions executable by the processor to update the building information modeling database to include the virtual alteration of the physical feature.

9. The head-mounted display device of claim 1, the instructions executable by the processor to display one or more of a world-locked holographic eligible location where the virtual operation may be performed and a world-locked holographic ineligible location where the virtual operation may not be performed.

10. The head-mounted display device of claim 1, the instructions executable by the processor to:
determine that the virtual operation relates to an event; and
based on the determination, communicate a timing alert to a user that associates the virtual operation with the event.

11. A method, comprising:
accessing a building information modeling database comprising building information data of a structure;
tracking a position of a head-mounted display device with respect to the structure, the head-mounted display device comprising an at least partially see-through display;
in response to a portal user input, displaying via the head-mounted display device a world-locked holographic portal on a surface of the structure, wherein the portal comprises a world-locked holographic representation of a portion of the structure otherwise hidden from view by the surface;
in response to an operation user input, performing a virtual operation on the structure; and
updating the building information modeling database based on the virtual operation.

12. The method of claim 11, wherein performing the operation comprises adding a virtual component to the structure, wherein the virtual component is selected from the building information data of the building information modeling database.

13. The method of claim 12, wherein the virtual component comprises a virtual load-bearing component, the method further comprising:
displaying a world-locked holographic representation of the virtual load-bearing component at a proposed location in the structure; and
receiving a load calculation for the virtual load-bearing component that is based on the proposed location of the virtual load-bearing component.

14. The method of claim 11, further comprising displaying on the surface a world-locked holographic installation template having installation dimensions corresponding to an actual component selected from the building information data of the building information modeling database.

15. The method of claim 12, further comprising:
capturing via the head-mounted display device one or more of depth data and image data of an actual component represented by the virtual component as installed in the structure; and
adding one or more of the depth data and the image data to the building information modeling database.

16. The method of claim 15, further comprising tagging the depth data and the image data in the building information modeling database with a component location of the actual component as installed in the structure.

17. The method of claim 11, further comprising:
capturing via the head-mounted display device a holographic comment regarding the structure that is geo-located with the holographic portal, the comment comprising one or more of text, audio commentary from a user, an image of the holographic representation of the portion of the structure otherwise hidden from view, and a timestamp of the comment; and
adding the holographic comment to the building information modeling database.

18. The method of claim 11, wherein performing the virtual operation comprises:
virtually altering a physical feature of the structure; and
updating the building information modeling database to include the virtual alteration of the physical feature.

19. The method of claim 11, further comprising:
determining that the virtual operation relates to an event; and
based on the determination, communicating a timing alert to a user that associates the virtual operation with the event.

20. A head-mounted display device, comprising:
a camera configured to capture images;
an at least partially see-through display;
a processor; and
a memory holding instructions executable by the processor to:
access a building information modeling database comprising building information data of a structure;
track a position of the head-mounted display device with respect to the structure;
in response to user input, display a world-locked holographic component at a proposed location in the structure, wherein the world-locked holographic component corresponds to an actual component that embodies a characteristic;
receive a calculation that is based on the proposed location of the holographic component and the characteristic; and
update the building information modeling database with the calculation.
